(19) United States
(12) Patent Application Publication
(10) Pub. No.: US 2017/0335186 A1
(43) Pub. Date: Nov. 23, 2017

(54) FLUORESCENT COMPOSITION, A LIGHT EMITTING ELEMENT PACKAGE COMPRISING SAME, AND AN ILLUMINATING DEVICE

(71) Applicant: LG INNOTEK CO., LTD., Seoul (KR)

(72) Inventors: Ji Wook MOON, Seoul (KR); Hyoung Jin KIM, Seoul (KR); Jeong Yoon MOON, Seoul (KR); Jae Wan CHOI, Seoul (KR)

(73) Assignee: LG INNOTEK CO., LTD., Seoul (KR)

(21) Appl. No.: 15/534,902

(22) PCT Filed: Dec. 9, 2015
(86) PCT No.: PCT/KR2015/013471

§ 371 Date: Jun. 9, 2017

(30) Foreign Application Priority Data
Dec. 9, 2014 (KR) 10-2014-0175673

(51) Int. Cl. C09K 11/77; C09K 11/61; C09K 11/66; C09K 11/67; H01L 33/50; F21V 29/70; H01L 33/48; C09K 11/08; H01L 33/06; H01L 33/30; H01L 33/32; H01L 33/40; H01L 33/44; H01L 33/54; H01L 33/56; H01L 33/62; H01L 33/60

(52) U.S. Cl. CPC C09K 11/7734; C09K 11/0883; C09K 11/617; C09K 11/665; C09K 11/675; H01L 33/504; F21V 29/70; H01L 33/486; H01L 33/06; H01L 33/30; H01L 33/32; H01L 33/405; H01L 33/44; H01L 33/54; H01L 33/56; H01L 33/62; H01L 33/60

(57) ABSTRACT

A phosphor composition of an embodiment and a light emitting device package including the same includes: a green phosphor excited by blue light to emit green light; a first red phosphor of a nitride series which is excited by the blue light and emits first red light; and a second red phosphor of a fluorine series which is excited by the blue light and emits second red light, and is capable of emitting white light without deterioration of optical characteristics at a high temperature while improving luminous flux and color reproduction rate as compared with a light emitting device package including a conventional phosphor composition.

### TECHNICAL FIELD

The embodiment relates to a phosphor composition including a plurality of phosphors having different chemical compositions, and a light emitting device package and a lighting apparatus including the same.

### BACKGROUND ART

Light emitting devices such as light emitting diodes using Group III-V or Group II-VI compound semiconductor materials and laser diodes may realize various colors such as red, green, blue, and ultraviolet rays through a development of a thin film growth technology and device materials, and may also realize white light with high efficiency by using fluorescent materials or by combining colors, thereby having advantages such as low power consumption, semi-permanent lifetime, fast response speed, safety, and environment friendliness compared to conventional light sources such as fluorescent lamps, incandescent lamps, etc.

Methods of realizing white light are divided into a method of bonding a fluorescent material on a blue or ultraviolet (UV) light emitting diode chip in a method of a single chip form, and a method of manufacturing in a multi-chip form and obtaining white light by combining thereof.

In the multi-chip form, there is a typical method of fabricating three kinds of chips of RGB (Red, Green, Blue) in combination. However, such a fabrication method has a problem in that color coordinates are different due to an unevenness of an operating voltage for each chip or a difference of an output of each chip due to a surrounding environment.

In addition, when the white light is realized by the single chip, a method has been used in which at least one phosphor is excited by using light emitted from a blue LED to obtain white light.

In addition, various kinds of phosphors have been developed to improve a color reproduction rate while having a high luminance value when a light emitting device package is applied. Recently, it has been reported that fluoro (F)-based red phosphors exhibit improved optical characteristics as compared with conventional red phosphors.

However, a fluoro-based phosphor is weak against heat or light as compared with the red phosphors used in the past, and therefore reliability is required to be improved.

### DISCLOSURE

### Technical Problem

The embodiment is directed to realizing a phosphor composition and a light emitting device package that include a green phosphor and a red phosphor, and particularly include two kinds of red phosphors as a red phosphor, thereby improving a luminance, having a high color rendering index, and having excellent reliability.

### Technical Solution

The embodiment provides a phosphor composition including: a green phosphor that is excited by blue light and emits green light; a first red phosphor of a nitride series that is excited by the blue light and emits first red light; and a second red phosphor of a fluoro series that is excited by the blue light and emits second red light.

An emission center wavelength of the green phosphor may be from 530 nm to 545 nm. An emission center wavelength of the first red phosphor may be 620 nm to 665 nm.

An emission center wavelength of the second red phosphor may be 620 nm to 640 nm.

The first red phosphor may be represented by a chemical formula of ASiAlN: Eu²⁺ (herein A is at least one of Sr and Ca).

The second red phosphor may be represented by a chemical formula of K₂MF₆:Mn⁴⁺ (herein M is at least one of Si, Ge, and Ti).

The green phosphor may be represented by β-SiAlON:Eu²⁺.

An emission wavelength of the blue light may be 350 nm to 500 nm.

The green phosphor may be included in a weight ratio of 20 wt % to 90 wt %, the first red phosphor may be included in a weight ratio of 0.1 wt % to 15 wt %, and the second red phosphor may be included in a weight ratio of 40 wt % to 90 wt %.

Another embodiment provides a light emitting device package including: a body part; a cavity formed on the body part; a light emitting device disposed in the cavity; a molding part surrounding the light emitting device and disposed in the cavity; and a phosphor composition included in the molding part and including a green phosphor, a first red phosphor of a nitride series, and a second red phosphor of a fluoro series, wherein the green phosphor is excited by blue light to emit green light, the first red phosphor is excited by the blue light and emits first red light, and the second red phosphor is excited by the blue light and emits second red light.

An emission center wavelength of the first red phosphor may be different from that of the second red phosphor.

A weight ratio of the first and second red phosphors may be 1:12 to 1:40.

Still another embodiment provides a lighting apparatus including a substrate; a light source module disposed on the substrate and including the above-described light emitting device package; and a heat dissipater that dissipates heat of the light source module.

### Advantageous Effects

A phosphor composition according to the embodiment and a light emitting device package including the same may simultaneously include a fluoro-based red phosphor and a nitride-based red phosphor as a red phosphor, thereby having an effect of improving optical characteristics such as a color reproduction rate and luminous flux, etc., as well as having stability under reliability evaluation conditions such as high temperature or high temperature and high humidity, etc.

### DESCRIPTION OF DRAWINGS

FIGS. 1A and 1B are views illustrating excitation wavelengths and emission wavelength regions of a green phosphor,

FIGS. 2A and 2B are views illustrating excitation wavelengths and emission wavelength regions of a first red phosphor,

FIGS. 3A and 3B are views illustrating excitation wavelengths and emission wavelength regions of a second red phosphor,

FIG. 4 is a view illustrating a light emitting device package according to one embodiment,

FIG. 5 is a view illustrating a light emitting device according to one embodiment,

FIGS. 6 and 7 are views illustrating a reliability evaluation result of the light emitting device package under a temperature condition of 60° C.,

FIGS. 8 and 9 are views illustrating a reliability evaluation result of the light emitting device package under a temperature condition of 85° C., and

FIGS. 10 and 11 are views illustrating a reliability evaluation result of the light emitting device package under the conditions of temperature and humidity of 85° C. and 85%.

### MODES OF THE INVENTION

Hereinafter, embodiments are provided in order to fully explain the invention, and will be described in detail with reference to accompanying drawings to help understanding of the invention.

In the description of embodiments of the present invention, it should be understood that when an element is referred to as being “on or under” another element, the term “on or under” refers to either a direct connection between two elements or an indirect connection between two elements having one or more elements formed therebetween. In addition, when the term “on or under” is used, it may refer to a downward direction as well as an upward direction with respect to an element.

Further, the relational terms such as “first” and “second,” “over/upper portion/above,” and “below/lower portion/under” do not necessarily require or include any physical or logical relationship or sequence between devices or elements and may also be used only to distinguish one device or element from another device or element.

Thicknesses of layers and areas in the drawings may be exaggerated, omitted, or schematically described for a convenient and precise description. In addition, the size of each component does not fully match the actual size thereof.

A phosphor composition of the embodiment may include a green phosphor that is excited by blue light and emits green light, a first red phosphor that is excited by the blue light and emits first red light, and a second red phosphor that emits second red light.

In the embodiment, the first red phosphor may be a phosphor of a nitride series and the second red phosphor may be a phosphor of a fluoro series.

A emission wavelength of the blue light that excites a phosphor included in the phosphor composition of the embodiment may be 350 nm to 500 nm.

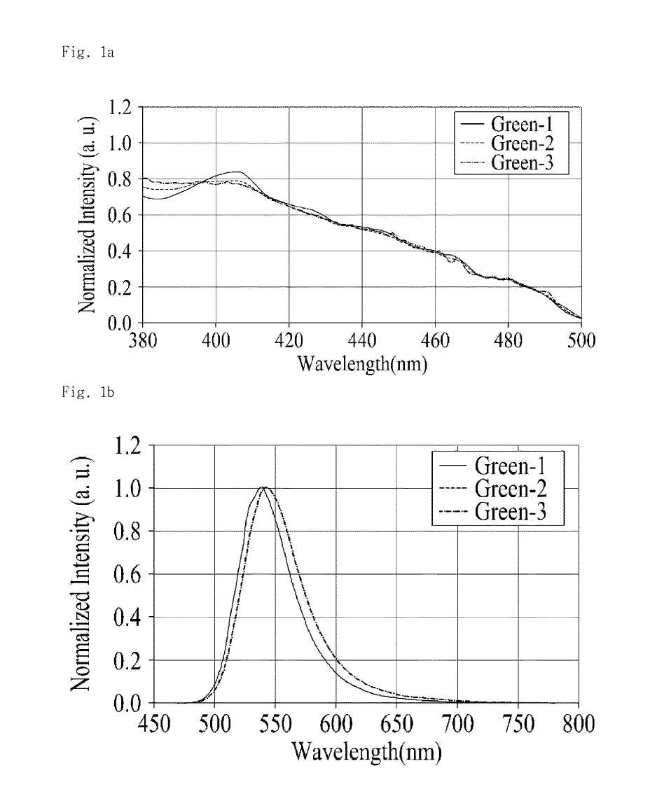

FIGS. 1A and 1B are views illustrating spectrums of excitation wavelengths and emission wavelengths of a green phosphor, respectively. In the graphs of FIGS. 1A to 1B, Green 1 to Green 3 represent spectrum data of excitation wavelengths and emission wavelengths for the green phosphors included in the phosphor composition of the embodiment, respectively.

Referring to FIG. 1A, the green phosphor may have an excitation wavelength of 380 nm to 500 nm. Specifically, the green phosphor may be excited mainly by light having a wavelength range of 380 nm to 420 nm.

Referring to FIG. 1B, an emission center wavelength of the green phosphor may be 530 nm to 545 nm.

The green phosphor included in the phosphor composition of the embodiment may be a β-SiAlON:Eu²⁺ phosphor. For example, the green phosphor may be Si6-zAlzOzN8-z:Eu²⁺ (here, 0<z<2).

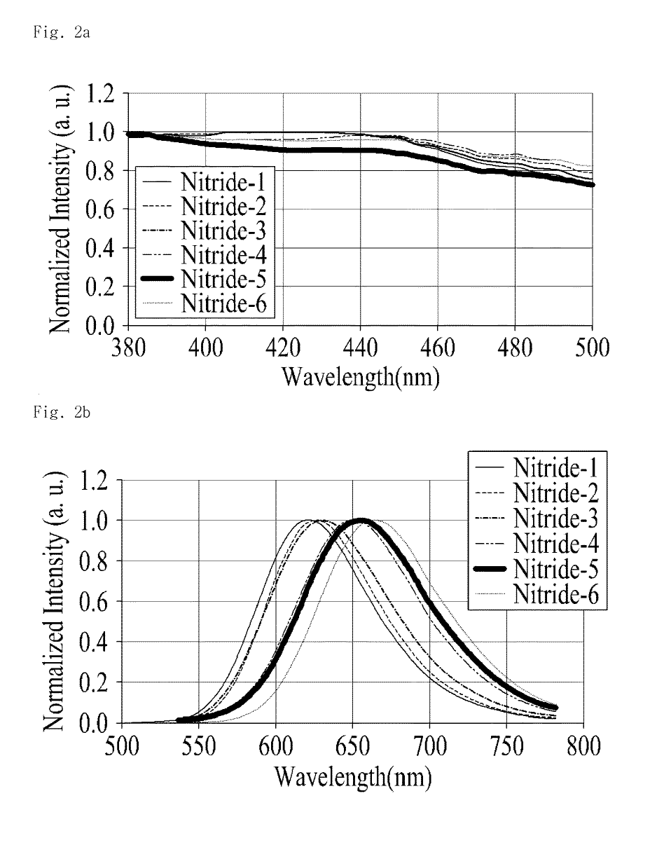

FIGS. 2A and 2B are views illustrating spectrums of excitation wavelengths and emission wavelengths of a first red phosphor, respectively. In FIGS. 2A and 2B, Nitride Red 1 to Nitride Red 6 represent spectrum data of excitation wavelengths and emission wavelengths for the first red phosphors included in the phosphor composition of the embodiment, respectively.

Referring to FIG. 2A, the first red phosphor may be excited in a wide wavelength region of 380 nm to 500 nm.

Further, referring to FIG. 2B, an emission center wavelength of the first red phosphor may be 620 nm to 665 nm.

The nitride-based first red phosphor may be represented by a chemical formula of ASiAlN:Eu²⁺. Here, A may be at least one of Sr (Strontium) and Ca (Calcium).

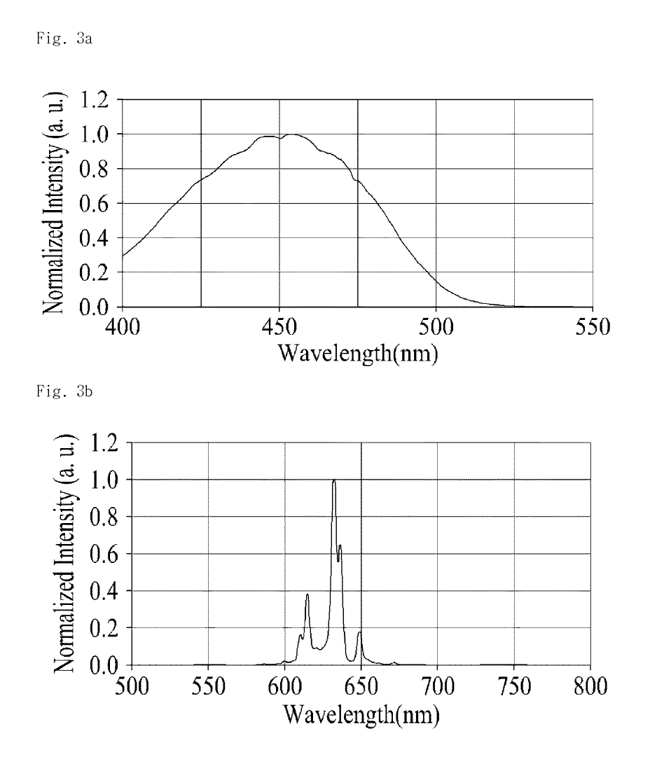

FIGS. 3A and 3B are views illustrating spectrums of excitation wavelengths and emission wavelengths of a second red phosphor, respectively.

Referring to FIG. 3A, the second red phosphor may be excited in a wavelength region of 400 nm to 500 nm. Specifically, an excitation wavelength of the second red phosphor may be 400 nm to 480 nm, and the excitation efficiency may be high in a wavelength range of about 450 nm.

Further, referring to FIG. 3B, an emission center wavelength of the second red phosphor may be 620 nm to 640 nm.

Specifically, in the emission wavelength spectrum of FIG. 3B, the second red phosphor may exhibit an emission peak near 630 nm to 635 nm.

The second red phosphor compared with the first red phosphor may have a sharp emission center wavelength in a narrow wavelength band of around 635 nm.

The embodiment may exhibit a high color reproduction rate by including the second red phosphor having a narrow full width at half maximum in the phosphor composition.

The second red phosphor, that is a fluoro-based phosphor, may be represented by a chemical formula of K2MF6:Mn⁴⁺. Here, M may be at least one of Si (Silicon), Ge (Germanium), and Ti (Titanium).

In the phosphor composition of the embodiment, the green phosphor may be included in a weight ratio of 20 wt % to 90 wt %, the first red phosphor may be included in a weight ratio of 0.1 wt % to 15 wt %, and the second red phosphor may be included in a weight ratio of 40 wt % to 90 wt % with respect to the weight of the whole phosphor.

When the weight ratio of the first red phosphor included is 0.1 wt % or less, an effect of improving the thermal stability using the content of the nitride-based red phosphor may not be exhibited. Meanwhile, when the weight ratio of the first red phosphor included is 15 wt % or more, an effect of improving the luminous flux and color reproduction rate by using of the second red phosphor may be reduced.

In addition, the green phosphor may be included in a weight ratio of 20 wt % to 50 wt %, the first red phosphor may be included in a weight ratio of 0.1 wt % to 10 wt %, and the second red phosphor may be included in a weight ratio of 40 wt % to 80 wt %.

For example, in the phosphor composition of the embodiment, the first red phosphor may be included in a weight ratio of 1 wt % to 5 wt %.

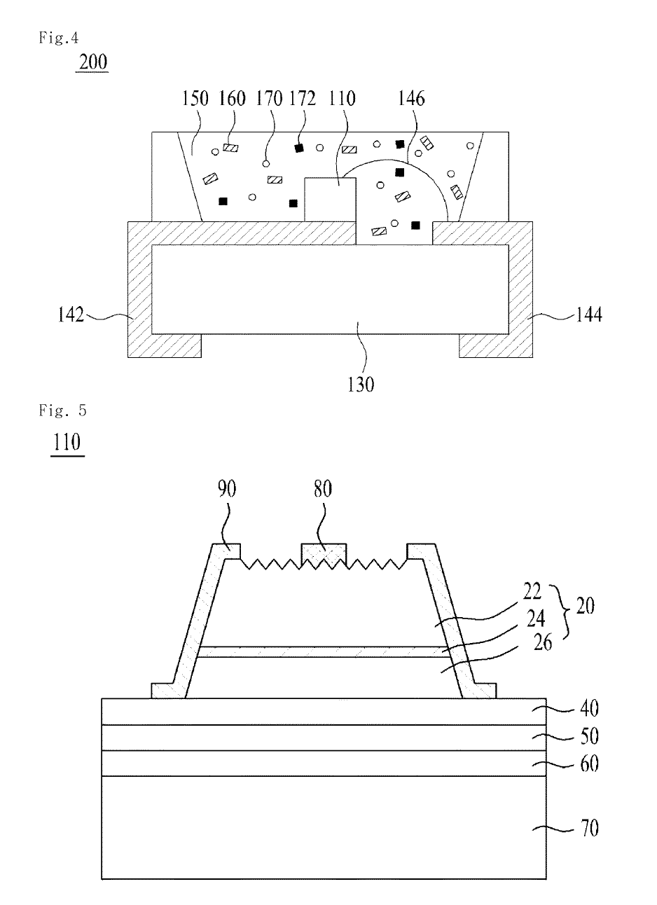

FIG. 4 is a view illustrating a light emitting device package 200 according to an embodiment.

The light emitting device package 200 according to the embodiment may include a body part 130, a cavity 150 formed on the body part 130, and a light emitting device 110 disposed in the cavity 150, wherein the body part 130 may include lead frames 142 and 144 for electrically connecting with the light emitting device 110.

The light emitting device 110 may be disposed on a bottom surface inside the cavity 150, and a molding part may be disposed in the cavity 150 while surrounding the light emitting device 110.

The molding part may include the phosphor composition of the embodiment as described above.

The body part 130 may be formed including a silicone material, a synthetic resin material, or a metal material, and may have the cavity 150 which consists of a side surface and a bottom surface, wherein a top thereof is open.

The cavity 150 may be formed in a cup shape, a concave container shape, or the like. A side surface of the cavity 150 may be formed perpendicular or inclined with respect to a bottom surface thereof, and may vary in size and shape.

A shape of the cavity 150 viewed from a top may be circular, polygonal, elliptical, or the like, and an edge thereof may have a curved shape, but is not limited thereto.

The body part 130 may include a first lead frame 142 and a second lead frame 144 to be electrically connected with the light emitting device 110. When the body part 130 is made of a conductive material such as a metal material or the like, although not shown, an insulating layer may be coated on a surface of the body part 130 to prevent an electrical short between the first and second lead frames 142 and 144.

The first lead frame 142 and the second lead frame 144 are electrically separated from each other and may supply a current to the light emitting device 110. In addition, the first lead frame 142 and the second lead frame 144 may reflect light generated from the light emitting device 110 to increase optical efficiency, and heat generated in the light emitting device 110 may be discharged to an outside.

The light emitting device 110 may be disposed in the cavity 150 and disposed on the body part 130 or on the first lead frame 142 or the second lead frame 144. The light emitting device 110 to be disposed may be a horizontal light emitting device or the like other than a vertical light emitting device.

In the embodiment shown in FIG. 4, the light emitting device 110 is disposed on the first lead frame 142, and may be connected to the second lead frame 144 via a wire 146. However, the light emitting device 110 may also be connected to the lead frame by a flip chip bonding method or a die bonding method in addition to a wire bonding method.

In the light emitting device package 200 of FIG. 4 according to the embodiment, the molding part may be formed while surrounding the light emitting device 110 and filling the inside of the cavity 150.

Further, the molding part may be formed to include a phosphor composition and resin of the embodiment including a plurality of phosphors 160, 170, and 172.

The molding part may include the resin and phosphors 160, 170, and 172, and may be disposed to surround the light emitting device 110 to protect the light emitting device 110.

The resin may be mixed and used with the phosphor composition in the molding part, and such resin may be in the form of any one of a silicone resin, an epoxy resin and an acrylic resin or a mixture thereof.

Further, the phosphors 160, 170, and 172 may be excited by the light emitted from the light emitting device 110 to emit light of which a wavelength is converted.

For example, the light emitted from the light emitting device 110 may be blue light, and the molding part of the light emitting device package 200 may include a green phosphor 160 that is excited by the blue light to emit green light, a first red phosphor 170 and a second red phosphor 172 that are excited by the blue light to emit red light.

Although not shown in the drawings, the molding part may be arranged in a dome shape that fills the cavity 150 and is higher than a side part height of the cavity 150, and may also be arranged in a deformed dome shape in order to adjust a light output angle of the light emitting device package 200. The molding part surrounds and protects the light emitting device 110, and may function as a lens for changing a path of the light emitted from the light emitting device 110.

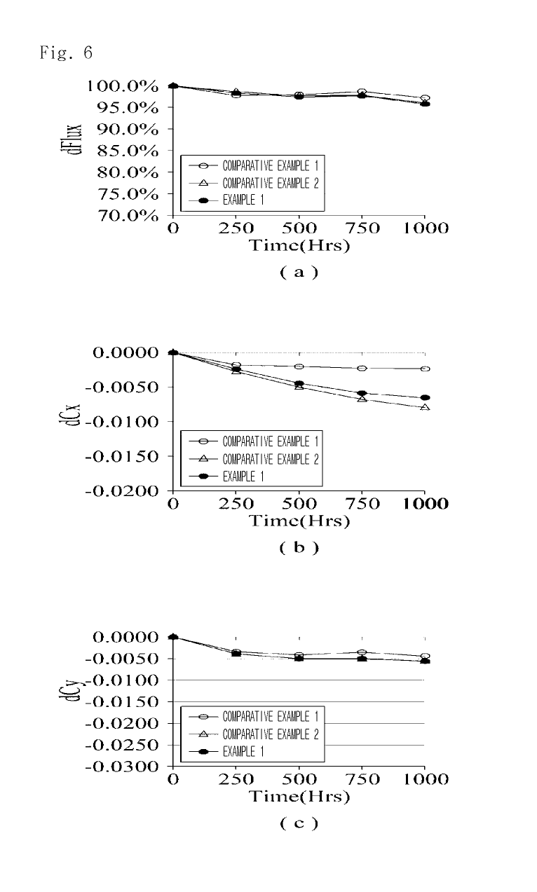

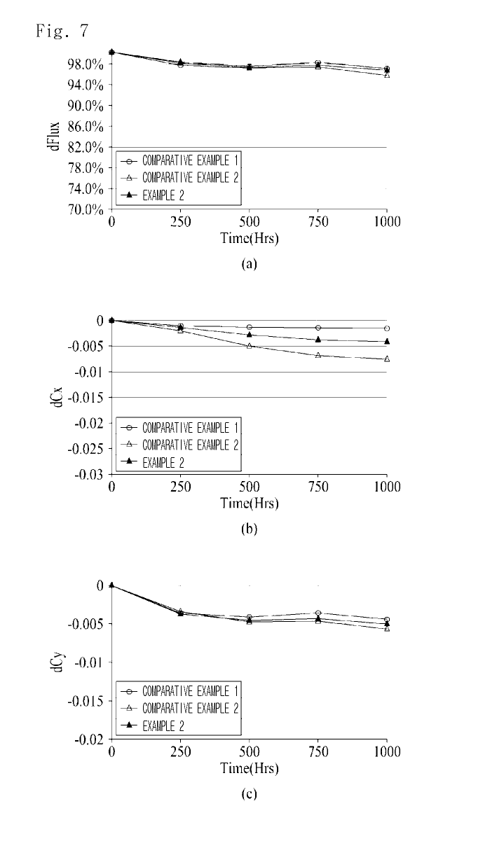

FIG. 5 is a view illustrating one embodiment of the light emitting device 110, and the light emitting device 110 may include a support substrate 70, a light emitting structure 20, an ohmic layer 40, and a first electrode 80.

The light emitting structure 20 includes a first conductivity type semiconductor layer 22, an active layer 24, and a second conductivity type semiconductor layer 26.

The first conductivity type semiconductor layer 22 may be formed with compound semiconductors such as Group III-V or Group II-VI, etc., and may be doped with a first conductive dopant. The first conductivity type semiconductor layer 22 may be formed of one or more among AlGaN, GaN, InAlGaN, AlGaAs, GaP, GaAs, GaAsP, and, AlGaInP, which are semiconductor materials having a composition formula of AlₓIn_{y}Ga_{(1-x-y)}N (0≦x≦1, 0≦y≦1, 0≦x+y≦1).

When the first conductivity type semiconductor layer 22 is an n-type semiconductor layer, the first conductive dopant may include n-type dopants such as Si, Ge, Sn, Se, and Te, etc. The first conductivity type semiconductor layer 22 may be formed as a single layer or a multilayer, but is not limited thereto.

The active layer 24 is disposed between the first conductivity type semiconductor layer 22 and the second conductivity type semiconductor layer 26, and may include any one of a double hetero structure, a single well structure, a multiple well structure, a single quantum well structure, a multi quantum well (MQW) structure, a quantum dot structure, and a quantum wire structure.

The active layer 24 may be formed of a well layer and a barrier layer, for example, at least one of pair structures of AlGaN/AlGaN, InGaN/GaN, InGaN/InGaN, AlGaN/GaN, InAlGaN/GaN, GaAs(InGaAs)/AlGaAs, and GaP(InGaP)/AlGaP, using compound semiconductors of Group III-V elements, but is not limited thereto. The well layer may be formed with a material having an energy band gap smaller than that of the barrier layer.

The second conductivity type semiconductor layer 26 may be formed with a semiconductor compound. The second conductivity type semiconductor layer 26 may be formed with compound semiconductors such as Group III-V or Group II-VI, etc., and may be doped with a second conductive dopant. The second conductivity type semiconductor layer 26 may be formed of one or more among AlGaN, GaNAlInN, AlGaAs, GaP, GaAs, GaAsP, and AlGaInP, which are semiconductor materials having a composition formula of InₓAl_{y}Ga_{1-x-y}N (0≦x≦1, 0≦y≦1, 0≦x+y≦1). For example, the second conductivity type semiconductor layer 26 may be formed with AlₓGa₍₁₋ₓ₎N.

When the second conductivity type semiconductor layer 26 is a p-type semiconductor layer, the second conductive dopant may be a p-type dopant such as Mg, Zn, Ca, Sr, Ba, etc. The second conductivity type semiconductor layer 26 may be formed as a single layer or a multilayer, but is not limited thereto.

The surface of the first conductivity type semiconductor layer 22 may form a pattern, thereby improving light extraction efficiency. Further, the first electrode 80 may be disposed on the surface of the first conductivity type semiconductor layer 22. Although not shown, the surface of the first conductivity type semiconductor layer 22 on which the first electrode 80 is disposed may not be patterned. The first electrode 80 may be formed as a single layer or a multilayer structure including at least one of aluminum (Al), titanium (Ti), chromium (Cr), nickel (Ni), and gold (Au).

A passivation layer 90 may be formed around the light emitting structure 20. The passivation layer 90 may be made of insulating materials, and the insulating material may be made of a nonconductive oxide or nitride. For example, the passivation layer 90 may be made of a silicon oxide (SiO2) layer, an oxynitride layer, or an aluminum oxide layer.

A second electrode may be disposed under the light emitting structure 20, and the ohmic layer 40 and a reflective layer 50 may act as the second electrode. GaN is disposed under the second conductivity type semiconductor layer 26, so that current or holes may be smoothly supplied to the second conductivity type semiconductor layer 26.

The ohmic layer 40 may have a thickness of about 200 Angstroms (A). The ohmic layer 40 may be formed to include at least one of indium tin oxide (ITO), indium zinc oxide (IZO), indium zinc tin oxide (IZTO), indium aluminum zinc oxide (IAZO), indium gallium zinc oxide (IGZO), indium gallium tin oxide (IGTO), aluminum zinc oxide (AZO), antimony tin oxide (ATO), gallium zinc oxide (GZO), IZO nitride (IZON), Al—GaZnO (AGZO), In—GaZnO (IGZO), ZnO, IrOx, RuOx, NiO, RuOx/ITO, Ni/IrOx/Au, and Ni/IrOx/Au/ITO, Ag, Ni, Cr, Ti, Al, Rh, Pd, Ir, Sn, In, Ru, Au, and Hf, but is not limited to the above materials.

The reflective layer 50 may be formed of a metal layer containing molybdenum (Mo), aluminum (Al), silver (Ag), nickel (Ni), platinum (Pt), rhodium (Rh), or an alloy including Al, Ag, Pt, or Rh. The reflective layer 50 effectively reflects the light generated in the active layer 24, thereby greatly improving the light extraction efficiency of the semiconductor device.

The support substrate 70 may be formed with conductive materials including metal, semiconductor materials, or the like. The metal in which electrical conductivity or thermal conductivity is excellent may be used for the support substrate 70, and since the heat generated during the operation of a semiconductor device must be sufficiently released, the support substrate 70 may be formed of materials (ex. metal, and the like) having high thermal conductivity.

For example, the support substrate 70 may be made of a material selected from the group consisting of molybdenum (Mo), silicon (Si), tungsten (W), copper (Cu), and aluminum (Al) or an alloy thereof. Moreover, gold (Au), a copper alloy (Cu Alloy), nickel (Ni), copper-tungsten (Cu—W), a carrier wafer (for example, any one of, GaN, Si, Ge, GaAs, ZnO, SiGe, SiC, SiGe, and Ga₂O₃ may be used) and the like may be included selectively.

The support substrate 70 may have a thickness of 50 μm to 200 μm to have a mechanical strength enough to be separated into separate chips through a scribing process and a breaking process without causing warping of the entire nitride semiconductors.

A junction layer 60 combines the reflective layer 50 and the support substrate 70, and may be formed with a material selected from the group consisting of gold (Au), tin (Sn), indium (In), aluminum (Al), silicon (Si), silver (Ag), nickel (Ni), and copper (Cu) or an alloy thereof.

The embodiment of the light emitting device 110 shown in FIG. 5 is an embodiment of a vertical light emitting device. However, in the embodiment of the light emitting device package 200 shown in FIG. 4, a horizontal light emitting device and a flip chip light emitting device may be arranged in addition to the vertical light emitting device shown in FIG. 5. At this time, the light emitting device 110 may emit light in a blue light wavelength range.

The embodiment of the light emitting device package of FIG. 4 including the light emitting device of the embodiment shown in FIG. 5 may emit white light.

Hereinafter, the results of a high temperature reliability test in the light emitting device package of the embodiment are described with reference to the tables and drawings.

Table 1 shows configurations of phosphor compositions of comparative examples and examples included in the embodiment of the light emitting device package used in high temperature, and high temperature and high humidity stability tests.

In Table 1, Comparative Example 1 includes only a green phosphor and a nitride-based red phosphor, that is a first red phosphor, Comparative Example 2 only includes a green phosphor and a fluoro-based red phosphor, that is a second red phosphor, and Example 1 and Example 2 show the composition ratios of the phosphor compositions including the first and second red phosphor and the green phosphor.

The first red phosphor and the second red phosphor may be included in a ratio according to the weight ratio of the red phosphors described above, and the weight ratio of the first red phosphor and the second red phosphor may be 1:12 to 1:30 as shown in Table 1 below.

In table 1, the weight ratio of each phosphor is shown as examples. But in the present invention, the range of the weight ratio of the phosphor composition is not limited to the following embodiment.

TABLE 1

| | Comparative | Comparative | | |
|---|---|---|---|---|
| Classification | Example 1 | Example 2 | Example 1 | Example 2 |
| Green phosphor | 80 wt % | 30 wt % | 38 wt % | 48 wt % |
| First red phosphor | 20 wt % | | 2 wt % | 4 wt % |
| Second red phosphor | | 70 wt % | 60 wt % | 48 wt % |

Tables 2 to 4 show the results of a high temperature reliability test at a temperature of 60° C. for the light emitting device package including the embodiment of phosphor compositions in Table 1.

Table 2 shows the result of measuring the change of a luminous flux at a temperature of 60° C. with the lapse of time. Further, Tables 3 and 4 show the color coordinate change value of the light emitting device package according to the time at a temperature of 60° C. Moreover, Table 3 corresponds to the change value of Cx, and Table 4 corresponds to the change value of Cy.

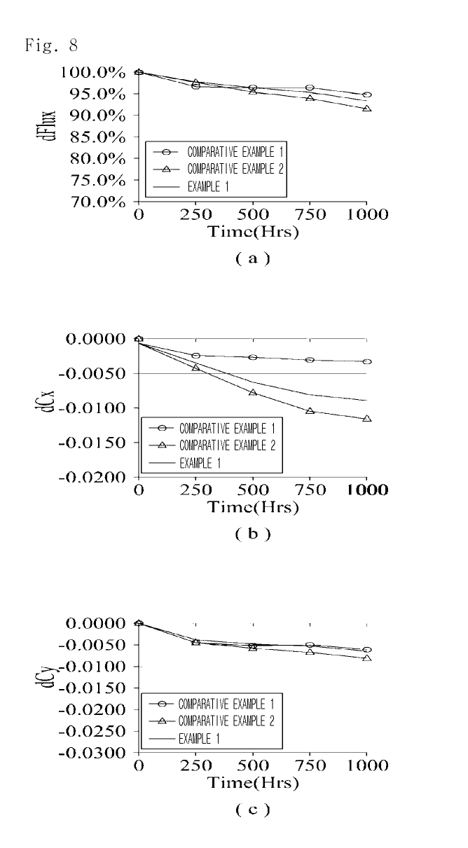

FIGS. 6A to 6C are graphs illustrating a luminous flux change (dFlux), a Cx change (dCx) and a Cy change (dCy) for Example 1 of Tables 2 to 4.

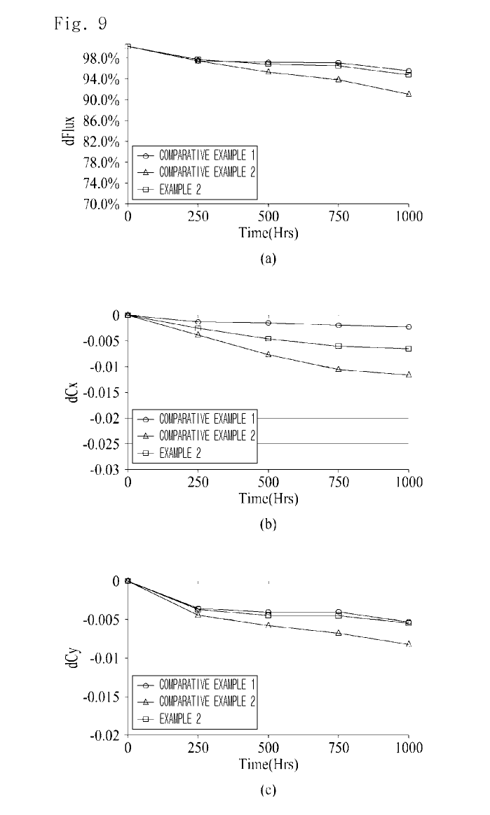

In addition, FIG. 7A to 7C are graphs illustrating a luminous flux change (dFlux), a Cx change (dCx), and a Cy change (dCy) for Example 2 among the results of Tables 2 to 4.

TABLE 2

| | Time (hrs) | | | | |
|---|---|---|---|---|---|
| Classification | 0 | 250 | 500 | 750 | 1000 |
| Comparative | 100.0% | 97.6% | 97.3% | 98.1% | 96.9% |
| Example 1 | | | | | |
| Comparative | 100.0% | 98.2% | 97.1% | 97.3% | 95.7% |
| Example 2 | | | | | |
| Example 1 | 100.0% | 98.0% | 96.9% | 97.2% | 95.6% |
| Example 2 | 100.0% | 98.0% | 97.2% | 97.6% | 96.6% |

TABLE 3

| Classification | 0 | 250 | 500 | 750 | 1000 |
|---|---|---|---|---|---|
| Comparative | 0.0000 | −0.0011 | −0.0014 | −0.0015 | −0.0017 |
| Example 1 | | | | | |
| Comparative | 0.0000 | −0.0020 | −0.0050 | −0.0069 | −0.0076 |
| Example 2 | | | | | |
| Example 1 | 0.0000 | −0.0019 | −0.0041 | −0.0054 | −0.0062 |
| Example 2 | 0.0000 | −0.0014 | −0.0029 | −0.0039 | −0.0042 |

TABLE 4

| Classification | 0 | 250 | 500 | 750 | 1000 |
|---|---|---|---|---|---|
| Comparative | 0.0000 | −0.0038 | −0.0042 | −0.0037 | −0.0044 |
| Example 1 | | | | | |
| Comparative | 0.0000 | −0.0036 | −0.0048 | −0.0048 | −0.0057 |
| Example 2 | | | | | |
| Example 1 | 0.0000 | −0.0037 | −0.0048 | −0.0046 | −0.0058 |
| Example 2 | 0.0000 | −0.0038 | −0.0047 | −0.0044 | −0.0051 |

When described with reference to Table 2 to Table 4 and FIG. 6, in the case of the light emitting device package including the phosphor composition of Example 1, a luminous flux value at the elapse of 1000 hours at 60° C. and a change value of the color coordinate Cy were similar to those in Comparative Example 2, but it can be seen that a change value of the color coordinate Cx is improved in comparison with that in Comparative Example 2.

That is, when compared with Comparative Example 2 including only the second red phosphor, it can be seen that the high temperature reliability at 60° C. is maintained or improved by including the first red phosphor in the case of Example 1.

In addition, referring to Table 2 and FIG. 7A, since a relative value of a luminous flux of the light emitting device package at the elapse of 1000 hours at 60° C. is higher than that of Comparative Example 2 including only the second red phosphor, in the case of Example 2, it can be seen that the reduction of the luminous flux is.

Referring to Tables 3 and 4 and FIGS. 7B and 7C for the amount of changes in color coordinates, in the case of Comparative Example 1 that includes only the green phosphor and the first red phosphor, that is a nitride-based phosphor, since the amount of change in color coordinates with the lapse of time is the smallest, it can be seen that the thermal stability is the most excellent. In the case of Comparative Example 2, since only a fluoro-based red phosphor having a relatively low thermal stability is included, a variation range of color coordinates is increased.

However, in the case of the light emitting device package including the phosphor composition having the composition ratio of Example 2, it can be seen that the degree of color change at a high temperature is decreased compared with Comparative Example 2 using the phosphor composition including only the second red phosphor.

Accordingly, referring to Tables 2 to 4 and FIGS. 6 and 7, in the phosphor composition according to the embodiments, the first red phosphor and the second red phosphor are simultaneously included. Accordingly, compared with Comparative Example 2 including only the second red phosphor, the thermal stability may be improved while maintaining the improved luminous flux, thereby having an effect of reducing the amount of change in luminous flux and color coordinates.

Tables 5 to 7 show changes in an optical characteristic measured at a high temperature condition of 85° C.

Table 5 shows a relative value of the luminous flux which changes with the time at the high temperature condition of 85° C., and Tables 6 and 7 show the color coordinate change values of the light emitting device package at a temperature of 85° C. with the lapse of time, and correspond to the change values of Cx and Cy, respectively.

In addition, FIGS. 8 and 9 show the change values of Tables 5 to 7, respectively, A shows a value of luminous flux change(dFlux), B shows a value of Cx change (dCx), C shows a value of Cy change (dCy), FIG. 8 is a graph illustrating the case of Example 1, and FIG. 9 is a graph illustrating the case of Example 2, respectively.

TABLE 5

| Classification | 0 | 250 | 500 | 750 | 1000 |
|---|---|---|---|---|---|
| Comparative | 100.0% | 97.2% | 96.9% | 96.9% | 95.4% |
| Example 1 | | | | | |
| Comparative | 100.0% | 97.3% | 95.2% | 93.8% | 91.1% |
| Example 2 | | | | | |
| Example 1 | 100.0% | 97.3% | 95.9% | 95.1% | 93.1% |
| Example 2 | 100.0% | 97.7% | 96.7% | 96.3% | 94.6% |

TABLE 6

| Classification | 0 | 250 | 500 | 750 | 1000 |
|---|---|---|---|---|---|
| Comparative | 0.0000 | −0.0014 | −0.0015 | −0.0020 | −0.0022 |
| Example 1 | | | | | |
| Comparative | 0.0000 | −0.0039 | −0.0076 | −0.0106 | −0.0116 |
| Example 2 | | | | | |
| Example 1 | 0.0000 | −0.0031 | −0.0059 | −0.0080 | −0.0089 |
| Example 2 | 0.0000 | −0.0026 | −0.0046 | −0.0060 | −0.0065 |

TABLE 7

| Classification | 0 | 250 | 500 | 750 | 1000 |
|---|---|---|---|---|---|
| Comparative | 0.0000 | −0.0039 | −0.0042 | −0.0041 | −0.0053 |
| Example 1 | | | | | |
| Comparative | 0.0000 | −0.0045 | −0.0059 | −0.0068 | −0.0083 |
| Example 2 | | | | | |
| Example 1 | 0.0000 | −0.0040 | −0.0049 | −0.0053 | −0.0064 |
| Example 2 | 0.0000 | −0.0037 | −0.0046 | −0.0046 | −0.0055 |

Referring to Table 5 and FIG. 8, in the case of Comparative Example 2, after the elapse of 1000 hours at 85° C., the luminous flux decreased by about 10% compared to the time before the start of the reliability test (0 hour). However, in Example 1, only a decrease of luminous flux of about 7% was observed. Therefore, it can be seen that the thermal stability at a high temperature of Example 1 is improved.

It can also be seen in the case of Example 1 that the variation of the color coordinates decreases in comparison with Comparative Example 2 in terms of the variation of the color coordinates shown in Tables 6 and 7 and FIGS. 8B and 8C.

Further, referring to Table 5 and FIG. 9A, in Example 2, only a decrease in luminous flux of about 5 to 6% is observed, and thus in the case of Example 2, it can be seen that the thermal stability at a high temperature is improved since the change of the luminous flux value is similar to that of Comparative Example 1.

Furthermore, referring to Tables 6 and 7 and FIGS. 9B and 9C illustrating the amount of change in color coordinates, in the case of Example 2, which further includes a nitride-based red phosphor in addition to a fluoro-based red phosphor, it can be seen that the variation range of the color coordinates decreases compared with Comparative Example 2.

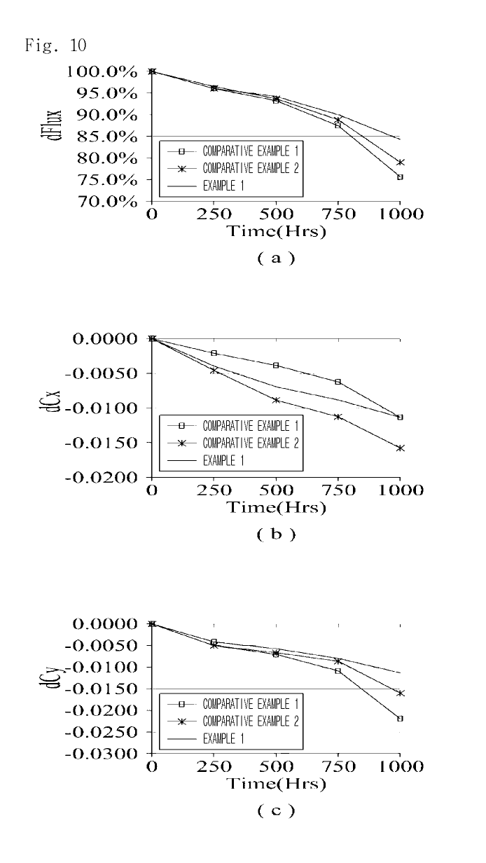

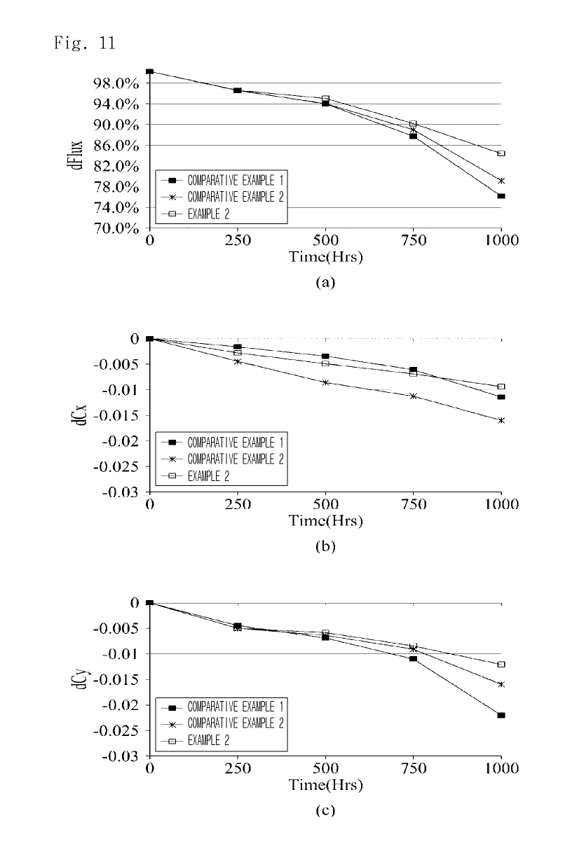

Tables 8 to 10 and FIGS. 10 and 11 show changes of an optical characteristic at 85° C. and 85% humidity conditions, which are reliability conditions of high temperature and high humidity.

Table 8 shows changes of luminous flux with the lapse of time, at 85° C. and 85% humidity conditions, Table 9 shows the change values of the Cx color coordinates, and Table 10 shows the change values of the Cy color coordinates.

TABLE 8

| Classification | 0 | 250 | 500 | 750 | 1000 |
|---|---|---|---|---|---|
| Comparative | 100.0% | 96.5% | 93.7% | 87.7% | 76.2% |
| Example 1 | | | | | |
| Comparative | 100.0% | 96.6% | 93.7% | 88.9% | 79.3% |
| Example 2 | | | | | |
| Example 1 | 100.0% | 96.1% | 94.1% | 90.3% | 84.6% |
| Example 2 | 100.0% | 96.4% | 94.8% | 90.1% | 84.4% |

TABLE 9

| Classification | 0 | 250 | 500 | 750 | 1000 |
|---|---|---|---|---|---|
| Comparative | 0.0000 | −0.0016 | −0.0034 | −0.0061 | −0.0113 |
| Example 1 | | | | | |
| Comparative | 0.0000 | −0.0045 | −0.0086 | −0.0112 | −0.0159 |
| Example 2 | | | | | |
| Example 1 | 0.0000 | −0.0034 | −0.0066 | −0.0088 | −0.0114 |
| Example 2 | 0.0000 | −0.0028 | −0.0049 | −0.0069 | −0.0093 |

TABLE 10

| Classification | 0 | 250 | 500 | 750 | 1000 |
|---|---|---|---|---|---|
| Comparative | 0.0000 | −0.0046 | −0.0071 | −0.0108 | −0.0217 |
| Example 1 | | | | | |
| Comparative | 0.0000 | −0.0051 | −0.0067 | −0.0092 | −0.0160 |
| Example 2 | | | | | |
| Example 1 | 0.0000 | −0.0051 | −0.0062 | −0.0085 | −0.0118 |
| Example 2 | 0.0000 | −0.0051 | −0.0060 | −0.0085 | −0.0121 |

Referring to Tables 8 to 10 and FIGS. 10 and 11, when compared with the high temperature (85° C.) condition, the variation of the optical characteristic is large in all cases of Comparative Examples 1 and 2 and Examples 1 and 2. However, it is possible to confirm an improved reliability test result in comparison with Comparative Example 2 in the case of Examples 1 and 2.

Each of the values in Tables 3 to 10 shows the color coordinate change values of the light emitting device package with the lapse of time, as shown in Table 2.

Specifically, when compared with the experiment at a high temperature condition (85° C.), it can be seen that the variations of the luminous flux and the color coordinates are smaller in the case of Examples 1 and 2 than those in the case of Comparative Example 1 in the condition of leaving for 1000 hours, thereby showing an improved reliability test result.

That is, in the case of the phosphor composition of the examples as described above in which the green phosphor and the red phosphors of different compound series are mixed and the light emitting device package including the same, it is possible to obtain an effect of improving the stability at high temperature or high temperature and high humidity by the influence of the nitride-based red phosphor which is the first red phosphor while improving the light characteristic of the luminous flux and a reproduction rate by the fluoro-based phosphor, that is the second red phosphor.

Hereinafter, an image display apparatus and a lighting apparatus will be described as one embodiment of a lighting system in which the light emitting device package 200 described above is disposed.

A plurality of light emitting device packages 200 according to the embodiment may be arrayed on a substrate, and a light guide plate, a prism sheet, a diffusion sheet, etc., which are optical members, may be disposed on the light path of the light emitting device package 200. The light emitting device package 200, the substrate, and the optical members may serve as a backlight unit.

In addition, a display device, an indicating device, and a lighting device including the light emitting device package 200 according to the embodiment may be realized.

Here, the display device may include a bottom cover, a reflective plate disposed on the bottom cover, a light emitting module which emits light, a light guide plate disposed in front of the reflective plate and configured to guide light emitted from the light emitting module in a forward direction, an optical sheet including prism sheets disposed in front of the light guide plate, a display panel disposed in front of the optical sheet, an image signal output circuit connected to the display panel and configured to supply an image signal to the display panel, and a color filter disposed in front of the display panel. Here, the bottom cover, the reflective plate, the light emitting module, the light guide plate, and the optical sheet may form a backlight unit.

Further, the lighting apparatus may include a substrate, a light source module including the light emitting device package 200 according to the embodiment, a heat dissipater which dissipates heat of the light source module, and a power supply which processes or converts an electrical signal provided from the outside and provides the processed or converted electrical signal to the light source module. For example, the lighting apparatus may include a lamp, a head lamp, or a street lamp, etc.

The head lamp may include a light emitting module including the light emitting device packages 200 disposed on a substrate, a reflector which reflects light emitted from the light emitting module in a predetermined direction, e.g., in a forward direction, a lens which refracts light reflected from the reflector in a forward direction, and a shade which blocks or reflects a part of the light which is reflected from the reflector and directed toward a lens so as to form a light distribution pattern desired by a designer.

In the case of the video display apparatus and the lighting apparatus described above, by using the phosphor composition of the embodiment as described above or the light emitting device package of the embodiment, the luminous flux and color reproduction rate may be improved. Moreover, it is possible to reduce the decrease of the optical characteristics such as the amount of change in the luminous flux and the color coordinates in a high temperature condition, thereby improving the reliability.

The above description of the embodiment is merely an example. It would be apparent to those of ordinary skill in the art that the embodiment may be easily embodied in many different forms without changing the technical idea or essential features thereof. For example, elements of the embodiments described herein may be modified and realized. Also, it will be understood that differences related to the modification and application are included in the scope of the present invention as defined by the following claims.

### INDUSTRIAL APPLICABILITY

A phosphor composition according to the embodiment, a light emitting device package and a lighting apparatus including the same, are capable of improving a light characteristic such as a luminous flux and a color reproduction rate and improving the stability at high temperature or high temperature and high humidity.

1. A phosphor composition comprising:
a green phosphor excited by blue light to emit green light;
a first red phosphor of a nitride series excited by the blue light to emit first red light; and
a second red phosphor of a fluoro series which is excited by the blue light to emit second red light.

2. The phosphor composition of claim 1,
wherein an emission center wavelength of the green phosphor is 530 nm to 545 nm.

3. The phosphor composition of claim 1,
wherein an emission center wavelength of the first red phosphor is 620 nm to 665 nm and an emission center wavelength of the second red phosphor is 620 nm to 640 nm.

4. The phosphor composition of claim 1,
wherein the first red phosphor is represented by a chemical formula of ASiAlN:Eu²⁺ (herein A is at least one of Sr and Ca).

5. The phosphor composition of claim 1,
wherein the second red phosphor is represented by a chemical formula of K₂MF₆:Mn⁴⁺ (herein M is at least one of Si, Ge, and Ti).

6. The phosphor composition of claim 1,
wherein the green phosphor is represented by a chemical formula of β-SiAlON:Eu²⁺.

7. The phosphor composition of claim 1,
wherein the green phosphor is included in a weight ratio of 20 wt % to 90 wt %, the first red phosphor is included in a weight ratio of 0.1 wt % to 15 wt %, and the second red phosphor is included in a weight ratio of 40 wt % to 90 wt %.

8. A light emitting device package comprising:
a body part;
a cavity formed on the body part;
a light emitting device disposed in the cavity;
a molding part surrounding the light emitting device and disposed in the cavity; and
a phosphor composition included in the molding part and including a green phosphor, a first red phosphor of a nitride series, and a second red phosphor of a fluoro series,
wherein the green phosphor is excited by blue light to emit green light, the first red phosphor is excited by the blue light and emits first red light, and the second red phosphor is excited by the blue light and emits second red light.

9. The light emitting device package of claim 8,
wherein an emission center wavelength of the green phosphor is 530 nm to 545 nm.

10. The light emitting device package of claim 8,
wherein an emission center wavelength of the first red phosphor is different from that of the second red phosphor.

11. The light emitting device package of claim 8,
wherein an emission center wavelength of the first red phosphor is 620 nm to 665 nm.

12. The light emitting device package of claim 8,
wherein an emission center wavelength of the second red phosphor is 620 nm to 640 nm.

13. The light emitting device package of claim 8,
wherein the first red phosphor is represented by a chemical formula of ASiAlN:Eu²⁺ (herein A is at least one of Sr and Ca).

14. The light emitting device package of claim 8,
wherein the second red phosphor is represented by a chemical formula of K₂MF₆:Mn⁴⁺ (herein M is at least one of Si, Ge, and Ti).

15. The light emitting device package of claim 8,
wherein the green phosphor is represented by β-SiAlON:Eu²⁺.

16. The light emitting device package of claim 8,
wherein an emission wavelength of the blue light is 350 nm to 500 nm.

17. The light emitting device package of claim 8,
wherein the green phosphor is included in a weight ratio of 20 wt % to 90 wt %, the first red phosphor is included in a weight ratio of 0.1 wt % to 15 wt %, and the second red phosphor is included in a weight ratio of 40 wt % to 90 wt %.

18. The light emitting device package of claim 8,
wherein a weight ratio of the first and second red phosphors is 1:12 to 1:30.

19. A lighting apparatus comprising:
a board;
a light source module disposed on the substrate and including the light emitting device package according to claim 8; and
a heat dissipater that dissipates heat of the light source module.

20. The lighting device of claim 19,
wherein the first red phosphor is represented by a chemical formula of ASiAlN:Eu²⁺ (herein A is at least one of Sr and Ca), and the second red phosphor is represented by a chemical formula of K₂MF₆:Mn⁴⁺ (herein M is at least one of Si, Ge, and Ti).
